(19) United States
(12) Patent Application Publication
(10) Pub. No.: US 2022/0342206 A1
(43) Pub. Date: Oct. 27, 2022

(54) OPTICAL DEVICE

(71) Applicant: HAMAMATSU PHOTONICS K.K., Hamamatsu-shi, Shizuoka (JP)

(72) Inventors: Shinya IWASHINA, Hamamatsu-shi, Shizuoka (JP); Shigeyuki NAKAMURA, Hamamatsu-shi, Shizuoka (JP); Naoto SAKURAI, Hamamatsu-shi, Shizuoka (JP); Yuki MORINAGA, Hamamatsu-shi, Shizuoka (JP); Daiki SUZUKI, Hamamatsu-shi, Shizuoka (JP)

(73) Assignee: HAMAMATSU PHOTONICS K.K., Hamamatsu-shi, Shizuoka (JP)

(21) Appl. No.: 17/763,285

(22) PCT Filed: Sep. 9, 2020
(86) PCT No.: PCT/JP2020/034183

§ 371 Date: Mar. 24, 2022

(30) Foreign Application Priority Data
Sep. 30, 2019 (JP) 2019-178842

(51) Int. Cl. G02B 26/10; G02B 26/08

(52) U.S. Cl. CPC G02B 26/103; G02B 26/0866

(57) ABSTRACT

In an optical device, a mirror surface is provided in a movable portion. A support portion supports the movable portion through an elastic connection portion. A force generator generates force in the movable portion. A drive controller outputs a drive signal that operates the force generator. The movable portion has a resonance frequency higher than a frequency of the drive signal output from the drive controller in a state before the elastic connection portion is heated. The movable portion swings due to the elastic deformation of the elastic connection portion in response to the force of the force generator. A heat controller acquires a signal that indicates a swing state of the movable portion and performs, based on a phase of the acquired signal, feedback control of heating of the elastic connection portion by a heater.

### TECHNICAL FIELD

The present invention relates to an optical device.

### BACKGROUND ART

An optical device including a movable portion provided with a mirror surface is known (for example, see Patent Literature 1). Patent Literature 1 discloses that the swing of the movable portion is controlled by a drive signal so that the movable portion swings at a resonance frequency.

### CITATION LIST

### Patent Literature

Patent Literature 1: Japanese Unexamined Patent Publication No. 2015-36782

### SUMMARY OF INVENTION

### Technical Problem

The resonance frequency of the movable portion may be different from the intended one due to individual differences depending on manufacturing variations and environmental temperatures. When the frequency of the drive signal for driving the movable portion fails to match the resonance frequency, there is a concern that a desired swing angle of the movable portion cannot be obtained and the operation of the movable portion becomes unstable. If the frequency of the drive signal is controlled to match the resonance frequency, it is possible to obtain a satisfactory amplitude in the mirror. However, in this configuration, it is difficult to move the mirror at a desired frequency.

An aspect of the present invention is to provide an optical device capable of achieving a stable swing of a movable portion at a desired frequency and a desired swing angle.

### Solution to Problem

An optical device according to an aspect of the present invention includes a mirror driver, a drive controller, a heater, and a heat controller. The mirror driver includes a movable portion, an elastic connection portion, a support portion, and a force generator. The movable portion is provided with a mirror surface. The elastic connection portion is connected to the movable portion. The support portion supports the movable portion through the elastic connection portion. The force generator generates force in the movable portion. The drive controller outputs a drive signal for operating the force generator. The heater heats the elastic connection portion. The heat controller controls the heater. The movable portion has a resonance frequency higher than a frequency of the drive signal output from the drive controller in a state before the elastic connection portion is heated. The movable portion swings due to the elastic deformation of the elastic connection portion in response to the force of the force generator. The heat controller acquires a signal indicating the swing state of the movable portion, and to perform, based on a phase of the acquired signal, feedback control of the heating of the elastic connection portion by the heater.

In one of the above aspects, the optical device includes a heater which heats the elastic connection portion. When the elastic connection portion is heated by the heater, the elastic modulus of the elastic connection portion changes. As a result, the resonance frequency of the movable portion also changes. Therefore, the optical device can easily change the resonance frequency of the movable portion. As a result, the optical device can stably swing the movable portion at a desired frequency and a desired swing angle. In such a configuration, it is required to accurately and quickly adjust the temperature of the elastic connection portion. However, for example, when the feedback control is performed based on the temperature detected by the temperature sensor, there is a time lag in detecting the temperature of the elastic connection portion that most contribute to the change in the resonance frequency. Since the heat transferred from the elastic connection portion to the support portion is detected when the temperature sensor is provided in the support portion, there is a time lag depending on the temperature transfer speed in the feedback control. The heat controller performs, based on the phase of the signal indicating the swing state of the movable portion, the feedback control of the heating of the elastic connection portion by the heater. Therefore, the optical device achieves at least more accurate and quick temperature adjustment than in the case of feedback control based on the temperature detected by the temperature sensor. Thus, the accuracy of changing the resonance frequency in the movable portion is also improved. In a state before the elastic connection portion is heated, the movable portion has a resonance frequency higher than the frequency of the drive signal output from the drive controller. In this case, the optical device can allow the resonance frequency of the movable portion to match the frequency of the drive signal only by the heating control of the heat controller. The optical device is made more compact than the case in which at least the cooling element is used.

In one of the above aspects, the movable portion may include a first movable portion and a second movable portion. The first movable portion is provided with the mirror surface. The second movable portion may surround the first movable portion. The elastic connection portion may include a first connection portion and a second connection portion. The first connection portion may elastically connect the first movable portion to the second movable portion. The second connection portion may elastically connect the second movable portion to the support portion.

In one of the above aspects, the heater may heat the first connection portion.

In one of the above aspects, the movable portion may have a resonance frequency higher than the frequency of the drive signal output from the drive controller in a state before the elastic connection portion is heated. In this case, the optical device can allow the resonance frequency of the movable portion to match the frequency of the drive signal only by the heating control of the heat controller. The optical device is made more compact than the case in which at least the cooling element is used.

In one of the above aspects, the heat controller may heat the elastic connection portion at a first power by the heater and then heat the elastic connection portion at a second power smaller than the first power.

In this case, the heat controller can roughly adjust the resonance frequency of the movable portion and then finely adjust the resonance frequency of the movable portion. As a result, the optical device can more accurately and quickly adjust the resonance frequency of the movable portion.

In one of the above aspects, the heater may include a first heater and a second heater. The first heater may provide a first heat to the elastic connection portion. The second heater may provide a second heat to the elastic connection portion, and the second heat may be smaller than the first heat. In this case, the heat controller can roughly adjust the resonance frequency of the movable portion by the first heater and finely adjust the resonance frequency of the movable portion by the second heater. Therefore, the optical device can more accurately and quickly adjust the resonance frequency of the movable portion.

In one of the above aspects, the first heater may be provided in the support portion. The second heater may be provided in at least one of the first connection portion and the movable portion. In this case, the optical device can more accurately and quickly adjust the resonance frequency of the movable portion in a compact configuration.

In one of the above aspects, the heater may include a laser irradiation unit which heats the elastic connection portion. In this case, the heater can more quickly heat the elastic connection portion. As a result, the optical device can more accurately and quickly change the resonance frequency of the movable portion.

In one of the above aspects, the heater may include a heating wire which heats the elastic connection portion. The heating wire may be provided in at least one of the elastic connection portion and the movable portion to be point-symmetrical with the center of gravity of the mirror surface as a point of symmetry. In this case, the heater can accurately heat the elastic connection portion in a compact configuration. Since the Lorentz forces generated in the heating wire cancel each other, the disturbance of the swing of the movable portion is suppressed.

In one of the above aspects, the heating wire may be provided in the movable portion to surround the mirror surface. In this case, the elastic connection portion is more quickly and accurately heated. Since the Lorentz forces generated in the heating wire cancel each other, the disturbance of the swing of the movable portion is suppressed.

In one of the above aspects, the heat controller may control the heating of the elastic connection portion by the heater so that the phase difference between the phase of the drive signal output from the drive controller and the phase of the signal indicating the swing state of the movable portion decreases. In this case, when comparing the phase of the drive signal with the phase of the signal indicating the swing state of the movable portion, the heating of the elastic connection portion can be more accurately controlled than the case of comparing the frequency of the drive signal with the frequency of the signal indicating the swing state of the movable portion. Thus, the optical device can more accurately obtain a desired swing angle at a desired frequency.

In one of the above aspects, the plurality of mirror units may be provided. Each mirror unit may include the mirror driver and the heater. The heat controller may control the heating of the elastic connection portion of each of the plurality of mirror units. In this case, the optical device can change the resonance frequency of each movable portion. Therefore, the optical device can swing each movable portion at a desired frequency and a desired swing angle.

In one of the above aspects, the movable portion of each of all mirror units provided in the optical device may have a resonance frequency higher than the frequency of the drive signal output from the drive controller in a state before the elastic connection portion connected to each movable portion is heated. The heat controller may heat the elastic connection portion of all mirror units by the heater. Since the cooling element has a relatively large size, the optical device is made more compact than the case in which the cooling element is used.

### Advantageous Effects of Invention

An aspect of the present invention provides an optical device capable of achieving a stable swing of a movable portion at a desired frequency and a desired swing angle.

### BRIEF DESCRIPTION OF DRAWINGS

FIG. 1 is a block diagram of an optical device according to this embodiment.

FIG. 2 is a schematic plan view of a mirror unit.

FIG. 3 is a schematic plan view of a mirror unit according to a modified example of this embodiment.

FIG. 4 is a schematic plan view of a mirror unit according to a modified example of this embodiment.

FIG. 5 is a flowchart illustrating a control method of the optical device.

FIG. 6 is a flowchart illustrating a phase stabilization process of a movable portion.

FIG. 7 is a diagram illustrating a relationship between a frequency of a drive signal and a resonance frequency of the movable portion of each mirror unit.

### DESCRIPTION OF EMBODIMENTS

Hereinafter, an embodiment of the present invention will be described in detail with reference to the accompanying drawings. Additionally, in the description, the same reference numerals are used for the same elements or elements having the same functions, and duplicate descriptions are omitted.

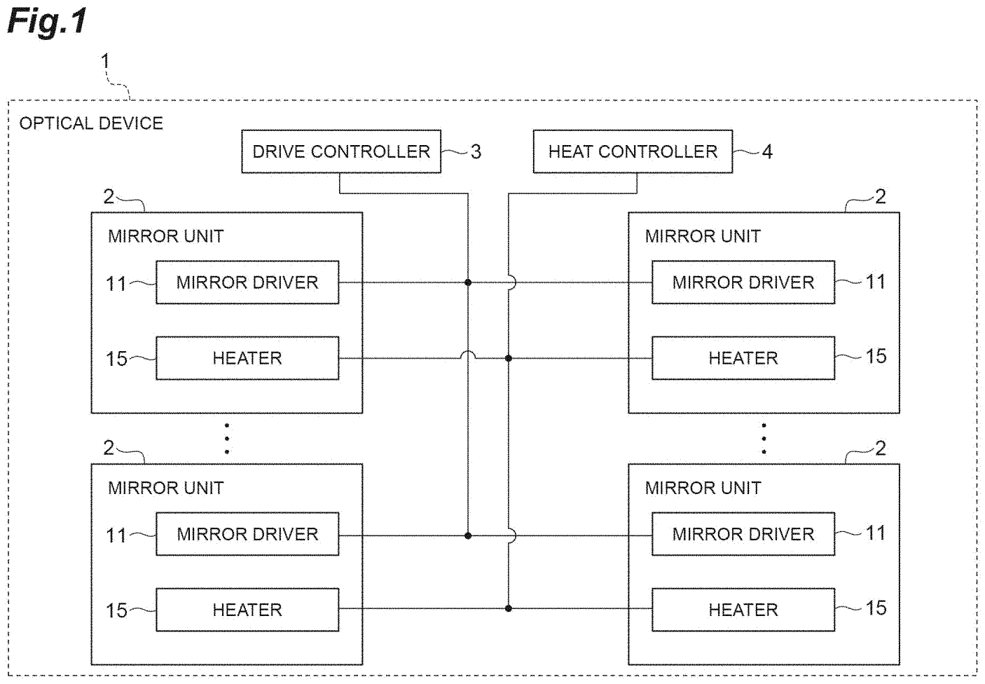

First, an outline of an optical device according to this embodiment will be described with reference to FIG. 1. FIG. 1 is a block diagram of the optical device. An optical device 1 includes a mirror surface and swings this mirror surface. The optical device 1 is used, for example, in an optical switch for optical communication, an optical scanner, and the like. The optical device 1 includes a drive controller 3, a heat controller 4, and at least one of mirror units 2. In this embodiment, the optical device 1 includes a plurality of the mirror units 2.

Each mirror unit 2 includes a mirror driver 11 and a heater 15. The mirror driver 11 is configured as, for example, an MEMS (Micro Electro Mechanical Systems) device. The mirror driver 11 is manufactured by using an MEMS technique such as patterning and etching. The heater 15 heats the mirror driver 11. The drive controller 3 outputs a drive signal and controls the driving of the mirror driver 11 by the drive signal. The heat controller 4 controls the heater 15.

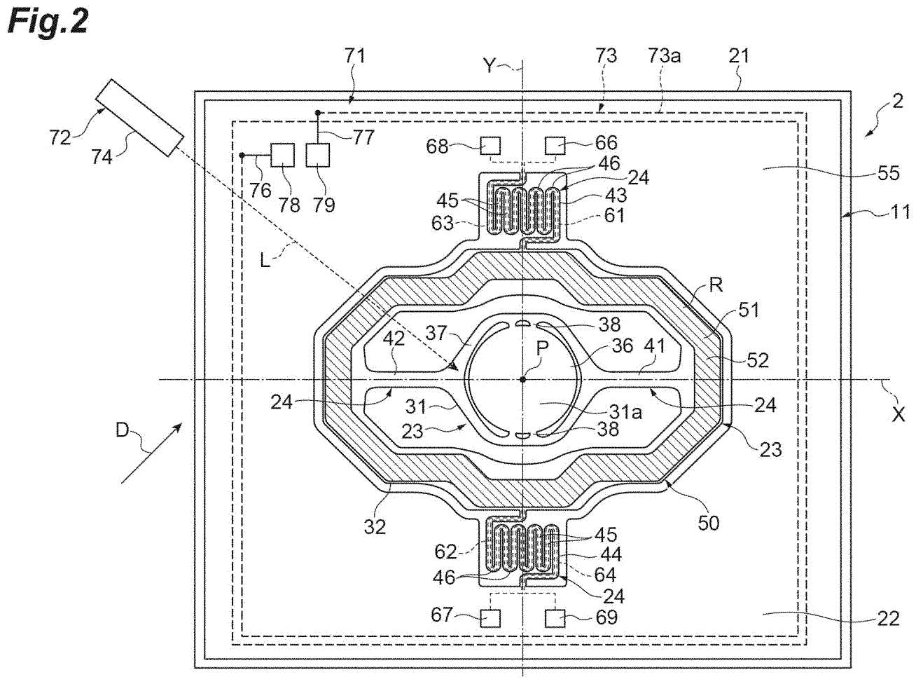

Next, a configuration of the mirror driver 11 will be described in detail with reference to FIG. 2. FIG. 2 is a schematic plan view of the mirror unit.

The mirror driver 11 includes, as illustrated in FIG. 2, a magnetic field generator 21, a support portion 22, a movable portion 23, and an elastic connection portion 24. The support portion 22, the movable portion 23, and the elastic connection portion 24 are integrally formed by, for example, an SOI (Silicon On Insulator) substrate. The support portion 22, the movable portion 23, and the elastic connection portion 24 are formed of, for example, silicon. At least one of the support portion 22, the movable portion 23, and the elastic connection portion 24 may be formed of metal.

The magnetic field generator 21 generates, for example, a magnetic field in a direction D inclined by 45° with respect to each of the X axis and the Y axis orthogonal to the X axis in a plan view. The direction D of the magnetic field generated by the magnetic field generator 21 may be inclined by an angle other than 45° with respect to the X axis and the Y axis in a plan view. In this embodiment, the magnetic field generator 21 includes a plurality of permanent magnets arranged by a Halbach array.

The support portion 22 has, for example, a quadrangular outer shape in a plan view and is formed in a frame shape. In this embodiment, the support portion 22 is separated from the permanent magnet of the magnetic field generator 21 and is disposed along with the permanent magnet in the direction orthogonal to the X axis and the Y axis.

The movable portion 23 is disposed in a frame formed by the support portion 22 when viewed from a direction orthogonal to the X axis and the Y axis while being separated from the magnetic field generator 21. The movable portion 23 includes a first movable portion 31 and a second movable portion 32. A mirror surface 31a is provided in the first movable portion 31. In the mirror driver 11, the second movable portion 32 swings around the Y axis and the first movable portion 31 swings around the X axis and the Y axis. The second movable portion 32 is formed in a frame shape and is disposed to surround the first movable portion 31. The second movable portion 32 is supported by the support portion 22.

As illustrated in FIG. 2, the first movable portion 31 includes a main body portion 36, an annular portion 37, and a pair of holding portions 38. In this embodiment, the main body portion 36 has a circular shape in a plan view. The main body portion 36 may be formed in any shape such as an elliptical shape, a quadrangular shape, and a rhombic shape. The mirror surface 31a is provided on the side opposite to the permanent magnet of the magnetic field generator 21 in a direction orthogonal to the X axis and the Y axis in the main body portion 36. The mirror surface 31a is formed of, for example, a metal film. The metal film is, for example, aluminum, an aluminum alloy, gold, or silver. In a plan view, the center of gravity P of the main body portion 36 matches the intersection of the X axis and the Y axis. In a plan view, the center of gravity P of the mirror surface 31a matches the intersection of the X axis and the Y axis.

The annular portion 37 is formed in an annular shape to surround the main body portion 36 in a plan view. The annular portion 37 has an octagonal outer shape in a plan view. The annular portion 37 may have an arbitrary outer shape such as a circular shape, an elliptical shape, a quadrangular shape, or a rhombic shape. The pair of holding portions 38 are arranged on both sides of the main body portion 36 along the Y axis and connect the main body portion 36 and the annular portion 37 to each other. In this way, the mirror surface 31a is provided in the main body portion 36 connected to the annular portion 37 through the plurality of holding portions 38. Therefore, deformation such as bending of the mirror surface 31a is suppressed even when the first movable portion 31 swings around the X axis at the resonance frequency level.

The elastic connection portion 24 includes a pair of first connection portions 41 and 42 and a pair of second connection portions 43 and 44. The first connection portions 41 and 42 and the second connection portions 43 and 44 are, for example, torsion bars. The pair of first connection portions 41 and 42 elastically connects the first movable portion 31 and the second movable portion 32 to each other. In other words, the first connection portions 41 and 42 are the elastic connection portions connected to the first movable portion 31 provided with the mirror surface 31a. The pair of second connection portions 43 and 44 elastically connects the support portion 22 and the second movable portion 32 to each other. In other words, the support portion 22 supports the first movable portion 31 through the first connection portions 41 and 42, the second movable portion 32, and the second connection portions 43 and 44.

The first connection portions 41 and 42 are arranged on both sides of the first movable portion 31 to pass through the X axis. The first movable portion 31 is sandwiched by the pair of first connection portions 41 and 42. The pair of first connection portions 41 and 42 connect the annular portion 37 of the first movable portion 31 and the second movable portion 32 to each other. Therefore, the first movable portion 31 is swingable around the X axis due to the elasticity of the pair of first connection portions 41 and 42.

Each of the first connection portions 41 and 42 extends in a linear shape along the X axis. In this embodiment, the width of the end portion on the side of the first movable portion 31 in each of the first connection portions 41 and 42 becomes wider as it becomes closer to the first movable portion 31. The width of the end portion on the side of the second movable portion 32 in each of the first connection portions 41 and 42 becomes wider as it becomes closer to the second movable portion 32. Therefore, the influence of the torsional stress acting on the first connection portions 41 and 42 is alleviated and the deterioration of the first connection portions 41 and 42 is suppressed.

The second connection portions 43 and 44 are arranged on both sides of the second movable portion 32 to pass through the Y axis. The second movable portion 32 is sandwiched by the pair of second connection portions 43 and 44. The pair of second connection portions 43 and 44 connect the second movable portion 32 and the support portion 22 to each other.

Each of the second connection portions 43 and 44 extends in a meandering manner in a plan view. Each of the second connection portions 43 and 44 includes a plurality of linear portions 45 and a plurality of folded-back portions 46. The linear portions 45 extend in a direction parallel to the Y axis and are arranged side by side in a direction parallel to the X axis. The folded-back portions 46 alternately connect both ends of the adjacent linear portions 45.

The mirror driver 11 further includes a force generator 50. The force generator 50 generates force in the first movable portion 31 and the second movable portion 32. The first movable portion 31 swings due to the elastic deformation of the first connection portions 41 and 42 in response to the force of the force generator 50. The second movable portion 32 swings due to the elastic deformation of the second connection portions 43 and 44 in response to the force of the force generator 50.

The force generator 50 includes a pair of driving coils 51 and 52, a plurality of wires 61, 62, 63, and 64, and a plurality of electrode pads 66, 67, 68, and 69. The driving coils 51 and 52 are provided in the second movable portion 32 to surround the first movable portion 31. Each of the driving coils 51 and 52 has a spiral shape in a plan view. Each of the driving coils 51 and 52 is wound around the first movable portion 31 a plurality of times. The pair of driving coils 51 and 52 are alternately arranged in the width direction of the second movable portion 32 in a plan view. In FIG. 2, a region R in which the driving coils 51 and 52 are arranged is illustrated by hatching.

Each of the driving coils 51 and 52 is formed by the damascene method. Each of the driving coils 51 and 52 is embedded in the second movable portion 32. Each of the driving coils 51 and 52 is covered with an insulating layer 55. Each of the driving coils 51 and 52 is embedded in the second movable portion 32. The insulating layer 55 is formed of, for example, silicon oxide, silicon nitride, silicon oxynitride, or the like. This insulating layer is integrally formed to cover the support portion 22, the first movable portion 31, the second movable portion 32, the first connection portions 41 and 42, and the second connection portions 43 and 44.

Each of the driving coils 51 and 52 is formed of a metal material having a density higher than the density of the material constituting the second movable portion 32. In this embodiment, the second movable portion 32 is formed of silicon, and each of the driving coils 51 and 52 is formed of copper. Each of the driving coils 51 and 52 may be formed of gold.

Each of the electrode pads 66, 67, 68, and 69 is provided in the support portion 22 and is exposed from the insulating layer 55 to the outside. Each of the electrode pads 66, 67, 68, and 69 is connected to the drive controller 3. The wire 61 is electrically connected to one end of the driving coil 51, and the electrode pad 66. The wire 61 extends from one end of the driving coil 51 to the electrode pad 66 through the second connection portion 43. The wire 62 is electrically connected to the other end of the driving coil 51, and the electrode pad 67. The wire 62 extends from the other end of the driving coil 51 to the electrode pad 67 through the second connection portion 44. Each of the wires 61 and 62 is formed by the damascene method, for example, similarly to the driving coils 51 and 52. Each of the wires 61 and 62 is covered with the insulating layer 55.

The wire 63 is electrically connected to one end of the driving coil 52, and the electrode pad 68. The wire 63 extends from one end of the driving coil 52 to the electrode pad 68 through the second connection portion 43. The wire 64 is electrically connected to the other end of the driving coil 52, and the electrode pad 69. The wire 64 extends from the other end of the driving coil 52 to the electrode pad 69 through the second connection portion 44. Each of the wires 63 and 64 is formed by the damascene method, for example, similarly to the driving coils 51 and 52. Each of the wires 63 and 64 is covered with the insulating layer 55.

The drive controller 3 outputs a drive signal for operating the force generator 50. The drive controller 3 inputs a drive signal to the force generator 50 of the mirror driver 11 with the above-described configuration. When a linear operating drive signal is input from the drive controller 3 to the driving coil 51 via the electrode pads 66 and 67 and the wires 61 and 62, the Lorentz force acts on the driving coil 51 due to the interaction with the magnetic field generated by the magnetic field generator 21. In accordance with the Lorentz force and the elastic force of the second connection portions 43 and 44, the second movable portion 32 is operated linearly around the Y axis together with the first movable portion 31 having the mirror surface 31a.

When a resonance operating drive signal is input from the drive controller 3 to the driving coil 52 via the electrode pads 68 and 69 and the wires 63 and 64, the Lorentz force acts on the driving coil 52 due to the interaction with the magnetic field generated by the magnetic field generator 21. Due to the resonance of the first movable portion 31 in response to the Lorentz force, the first movable portion 31 having the mirror surface 31a resonates around the X axis. Specifically, when the drive signal from the drive controller 3 is input to the driving coil 52, the second movable portion 32 slightly vibrates around the X axis at the frequency of the drive signal. This vibration is transmitted to the first movable portion 31 through the first connection portions 41 and 42 so that the first movable portion 31 swings around the X axis. If the resonance frequency of the first movable portion 31 around the X axis matches the frequency of the drive signal, the first movable portion 31 stably swings around the X axis at this frequency. In this embodiment, the first movable portion 31 of each of all mirror units 2 provided in the optical device 1 has a resonance frequency higher than the frequency of the drive signal output from the drive controller 3 in a state before the first connection portions 41 and 42 connected to the first movable portion 31 are heated.

Next, a configuration of the heater 15 will be described in detail with reference to FIG. 2. In the optical device 1, the plurality of heaters 15 are provided in each mirror unit 2. The heat controller 4 acquires a signal indicating the swing state of the first movable portion 31 and performs, based on the phase of the signal, feedback control of the heating of the first connection portions 41 and 42 by the heater 15. In this embodiment, the signal indicating the swing state is a signal indicating the relative position of the first movable portion 31 with respect to the support portion 22. In other words, the signal indicating the swing state is a signal indicating the phase of the swing angle of the first movable portion 31. The heat controller 4 controls the heating of the first connection portions 41 and 42 of each of the plurality of mirror units 2. In this embodiment, the heat controller 4 heats the first connection portions 41 and 42 of all mirror units 2 by the heater 15.

The heat controller 4 quickly heats the first connection portions 41 and 42 and slowly heats the first connection portions 41 and 42, by the heater 15. Accordingly, the heat controller 4 finely adjusts the temperature of the first connection portions 41 and 42. In other words, by the heater, the heat controller 4 heats the first connection portions 41 and 42 at the first power, and then heats the first connection portions 41 and 42 at the second power smaller than the first power.

In this embodiment, each heater 15 includes a first heater 71 and a second heater 72. The heat provided by the first heater 71 to the first movable portion 31 and the heat provided by the second heater 72 to the first movable portion 31 are different from each other. The first heater 71 and the second heater 72 heat the first movable portion 31 by, for example, irradiating a laser or generating heat from the heating wire.

The first heater 71 provides a first heat to the first connection portions 41 and 42 in response to a signal from the heat controller 4. The second heater 72 provides a second heat, and the second heat is smaller than the first heat to the first connection portions 41 and 42 in response to a signal from the heat controller 4. The heat controller 4 heats the first connection portions 41 and 42 largely by the first heater 71 and heats the first connection portions 41 and 42 less by the second heater 72. Accordingly, the heat controller 4 adjusts the temperature of the first connection portions 41 and 42.

In this embodiment, as illustrated in FIG. 2, the mirror unit 2 includes a heating wire portion 73 and a laser irradiation unit 74. The heating wire portion 73 and the laser irradiation unit 74 function as the heater 15 which heats the first connection portions 41 and 42. In other words, the heater 15 includes the heating wire portion 73 and the laser irradiation unit 74.

The heating wire portion 73 generates heat according to the applied voltage. The voltage applied to the heating wire portion 73 is controlled by the heat controller 4. The heating wire portion 73 includes a heating wire 73a. The mirror driver 11 further includes wires 76 and 77 and electrode pads 78 and 79. The heating wire 73a is provided in the support portion 22 to surround the second movable portion 32. The heating wire 73a has a spiral shape in a plan view.

The heating wire 73a is formed of metal or semiconductor. For example, the heating wire 73a is formed of copper or an aluminum alloy. The heating wire 73a may be formed by a diffusion layer.

Each of the electrode pads 78 and 79 is provided in the support portion 22 and is exposed from the insulating layer 55 to the outside. The wire 76 is electrically connected to one end of the heating wire 73a and the electrode pad 78. The wire 77 is electrically connected to the other end of the heating wire 73a and the electrode pad 79. The electrode pads 78 and 79 are electrically connected to the heat controller 4. When a voltage is applied to the electrode pads 78 and 79, the heating wire 73a generates heat so that the movable portion 23 is heated on the whole. Accordingly, the first connection portions 41 and 42 are heated. The heating wire 73a is included in the first heater 71.

The laser irradiation unit 74 irradiates at least one of the first movable portion 31 and the pair of first connection portions 41 and 42 with a laser. The laser irradiation unit 74 is electrically connected to the heat controller 4. The intensity of the laser emitted from the laser irradiation unit 74 is controlled by the heat controller 4. In this embodiment, the laser irradiation unit 74 irradiates the first movable portion 31 with a laser. Accordingly, the first movable portion 31 is heated and the heat is transferred from the heated first movable portion 31 to the pair of first connection portions 41 and 42. As a result, the first connection portions 41 and 42 are heated. Even when the mirror surface 31a of the first movable portion 31 is irradiated with a laser, the first connection portions 41 and 42 are heated by the transfer of the heat. In this embodiment, the laser irradiation unit 74 is included in the second heater 72.

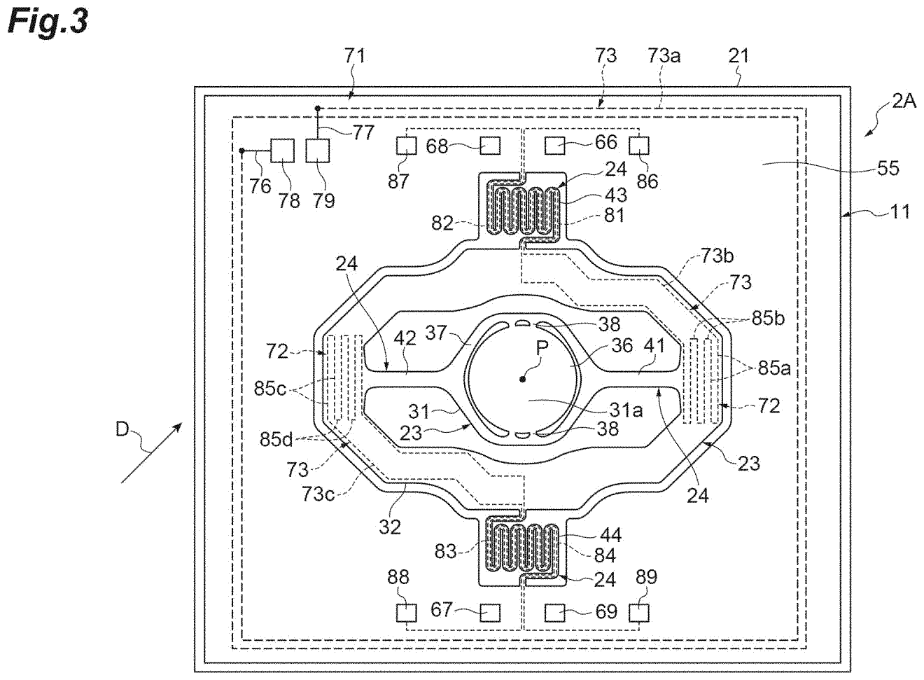

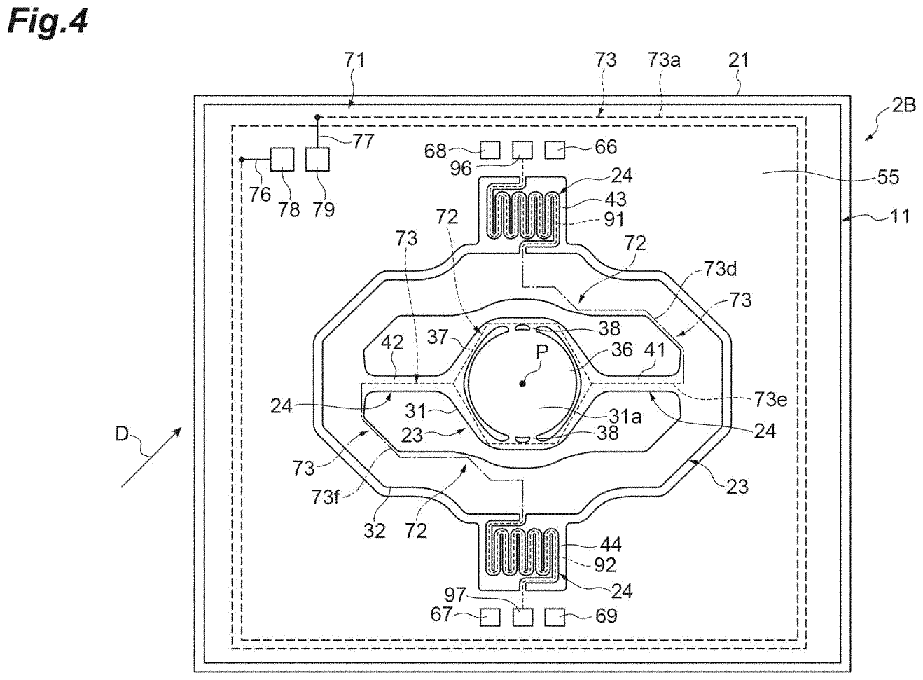

Next, mirror units of optical devices according to modified examples of this embodiment will be described with reference to FIGS. 3 and 4. FIG. 3 is a schematic plan view of the mirror unit according to the modified example of this embodiment. This modified example is substantially similar to or the same as the above-described embodiment. This modified example is different from the above-described embodiment in that the heater 15 fails to include the laser irradiation unit 74 and the heating wire portion 73 includes heating wires 73b and 73c. Hereinafter, a difference between the above-described embodiment and the modified example will be mainly described. Further, the pair of driving coils 51 and 52 and the plurality of wires 61, 62, 63, and 64 are omitted in FIG. 3.

In a mirror unit 2A of this modified example, the heating wire portion 73 includes the heating wires 73b and 73c in addition to the heating wire 73a as illustrated in FIG. 3. The mirror driver 11 further includes wires 81, 82, 83, and 84 and electrode pads 86, 87, 88, and 89. The heating wires 73b and 73c are provided in the second movable portion 32. The heating wires 73b and 73c are included in the second heater 72. The heating wires 73b and 73c are provided to be point-symmetrical with the center of gravity of the mirror surface 31a as a point of symmetry.

The heating wire 73b extends from the connection portion between the second connection portion 43 and the second movable portion 32 toward the connection portion between the second movable portion 32 and the first connection portion 41. The heating wire 73b meanders at the connection portion between the second movable portion 32 and the first connection portion 41 and then extends toward the connection portion between the second connection portion 43 and the second movable portion 32. The heating wire 73b includes a plurality of linear portions 85a and a plurality of folded-back portions 85b at the connection portion between the second movable portion 32 and the first connection portion 41. The linear portions 75b extend in a direction parallel to the Y axis and are arranged side by side in a direction parallel to the X axis. The folded-back portions 85b alternately connect both ends of the adjacent linear portions 85a.

The heating wire 73c extends from the connection portion between the second connection portion 44 and the second movable portion 32 toward the connection portion between the second movable portion 32 and the first connection portion 42. The heating wire 73c meanders at the connection portion between the second movable portion 32 and the first connection portion 42 and then extends toward the connection portion between the second connection portion 44 and the second movable portion 32. The heating wire 73c includes a plurality of linear portions 85c and a plurality of folded-back portions 85d at the connection portion between the second movable portion 32 and the first connection portion 42. The linear portions 85c extend in a direction parallel to the Y axis and are arranged side by side in a direction parallel to the X axis. The folded-back portions 85d alternately connect both ends of the adjacent linear portions 85c.

In this modified example, the heating wires 73b and 73b are formed by sputtering and photolithography. The heating wires 73b and 73c may be exposed from the insulating layer 55. The heating wires 73b and 73c may be formed by the damascene method, for example, similarly to the driving coils 51 and 52. In this case, the heating wires 73b and 73c are embedded in the second movable portion 32 in a layer different from each of the driving coils 51 and 52. In this case, the heating wires 73b and 73c are covered with the insulating layer 55.

The heating wires 73b and 73c are formed of metal or semiconductor. For example, the heating wires 73b and 73c are formed of copper or an aluminum alloy. The heating wires 73b and 73c may be formed by a diffusion layer.

The wire 81 is electrically connected to one end of the heating wire 73b, and the electrode pad 86. The wire 81 extends from one end of the heating wire 73b to the electrode pad 86 through the second connection portion 43. The wire 82 is electrically connected to the other end of the heating wire 73b, and the electrode pad 87. The wire 82 extends from the other end of the heating wire 73b to the electrode pad 87 through the second connection portion 43. Each of the wires 81 and 82 is formed by the damascene method and is covered with the insulating layer 55, for example, similarly to the driving coils 51 and 52.

The wire 83 is electrically connected to one end of the heating wire 73c, and the electrode pad 88. The wire 83 extends from one end of the heating wire 73c to the electrode pad 88 through the second connection portion 44. The wire 84 is electrically connected to the other end of the heating wire 73c, and the electrode pad 89. The wire 84 extends from the other end of the heating wire 73c to the electrode pad 89 through the second connection portion 44. Each of the wires 83 and 84 is formed by the damascene method, for example, similarly to the driving coils 51 and 52. Each of the wires 83 and 84 is covered with the insulating layer 55.

The electrode pads 86, 87, 88, and 89 are electrically connected to the heat controller 4. When a voltage is applied to the electrode pads 86 and 87 by the heat controller 4, the heating wire 73b generates heat so that the second movable portion 32 is heated. Particularly, the connection portion between the second movable portion 32 and the first connection portion 41 is heated. When the heat is transferred from the heated portion to the first connection portion 41, the first connection portion 41 is heated. When a voltage is applied to the electrode pads 88 and 89 by the heat controller 4, the heating wire 73c generates heat so that the second movable portion 32 is heated. Particularly, the connection portion between the second movable portion 32 and the first connection portion 42 is heated. When the heat is transferred from the heated portion to the first connection portion 42, the first connection portion 42 is heated. The heating wires 73b and 73c are included in the second heater 72.

Next, the mirror unit of the optical device according to the modified example of this embodiment will be described with reference to FIG. 4. FIG. 4 is a schematic plan view of the mirror unit according to the modified example of this embodiment. This modified example is substantially similar to or the same as the above-described embodiment. This modified example is different from the above-described embodiment in that the heater 15 fails to include the laser irradiation unit 74 and the heating wire portion 73 includes heating wires 73d, 73e, and 73f. Hereinafter, a difference between the above-described embodiment and the modified example will be mainly described. Further, the pair of driving coils 51 and 52 and the plurality of wires 61, 62, 63, and 64 are omitted in FIG. 4.

In a mirror unit 2B of this modified example, the heating wire portion 73 includes the heating wires 73d, 73e, and 73f in addition to the heating wire 73a as illustrated in FIG. 4. The mirror driver 11 further includes wires 91 and 92 and electrode pads 96 and 97. The heating wires 73d, 73e, and 73f are provided in the second movable portion 32. The heating wires 73d and 73f are indicated by the one-dotted chain line. The heating wire 73e is indicated by the chain line. The heating wires 73d, 73e, and 73f are included in the second heater 72. The heating wires 73d, 73e, and 73f are provided to be point-symmetrical with the center of gravity of the mirror surface 31a as a point of symmetry.

The heating wire 73d extends from the connection portion between the second connection portion 43 and the second movable portion 32 to the connection portion between the second movable portion 32 and the first connection portion 41. The heating wire 73e is connected to the heating wire 73d at the connection portion between the second movable portion 32 and the first connection portion 41. The heating wire 73e is provided in the annular portion 37 of the first movable portion 31. The heating wire 73e extends from the connection portion between the second movable portion 32 and the first connection portion 41 to the connection portion between the first movable portion 31 and the first connection portion 41 along the first connection portion 41. The heating wire 73e is divided into two parts at the connection portion between the first movable portion 31 and the first connection portion 41 and extends along the edge of the first movable portion 31 to surround the mirror surface 31a. Two divided heating wires 73e are connected to each other at the connection portion between the first movable portion 31 and the first connection portion 42. The heating wire 73e extends from the connection portion between the first movable portion 31 and the first connection portion 42 to the connection portion between the second movable portion 32 and the first connection portion 42 along the first connection portion 42. The heating wire 73e is connected to the heating wire 73f at the connection portion between the second movable portion 32 and the first connection portion 42. The heating wire 73f extends from the connection portion between the second movable portion 32 and the first connection portion 42 to the connection portion between the second connection portion 44 and the second movable portion 32.

In this modified example, the heating wires 73d, 73e, and 73f are formed by the damascene method, for example, similarly to the driving coils 51 and 52. The heating wires 73d, 73e, and 73f are embedded in the first movable portion 31, the second movable portion 32, and the first connection portions 41 and 42. The heating wires 73d, 73e, and 73f are covered with the insulating layer 55. The heating wires 73d, 73e, and 73f may be embedded in the first movable portion 31, the second movable portion 32, and the first connection portions 41 and 42 in a layer different from each of the driving coils 51 and 52. The heating wires 73d, 73e, and 73f may be exposed from the insulating layer 55.

The heating wires 73d, 73e, and 73f are formed of metal or semiconductor. For example, the heating wires 73d, 73e, and 73f are formed of copper or an aluminum alloy. The heating wires 73d, 73e, and 73f may be formed by a diffusion layer. The heating wire 73e is preferably formed by a diffusion layer or polysilicon.

The wire 91 is electrically connected to one end of the heating wire 73d and the electrode pad 96. The wire 91 extends from one end of the heating wire 73d to the electrode pad 96 through the second connection portion 43. The wire 92 is electrically connected to one end of the heating wire 73f and the electrode pad 97. The wire 92 extends from one end of the heating wire 73f to the electrode pad 97 through the second connection portion 44. Each of the wires 91 and 92 is formed by the damascene method, for example, similarly to the driving coils 51 and 52. Each of the wires 91 and 92 is covered with the insulating layer 55.

The electrode pads 96 and 97 are electrically connected to the heat controller 4. When a voltage is applied to the electrode pads 96 and 97 by the heat controller 4, the heating wires 73d, 73e, and 73f generate heat so that the first movable portion 31, the second movable portion 32, and the first connection portions 41 and 42 are heated. The heating wires 73d, 73e, and 73f are included in the second heater 72.

As described above, in the modified example illustrated in FIGS. 3 and 4, the first heater 71 is provided in the support portion 22. The second heater 72 is provided in at least one of the first connection portions 41 and 42, the first movable portion 31, and the second movable portion 32.

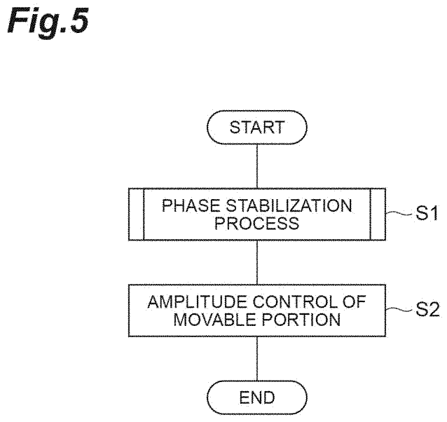

Next, an example of a control method of the optical device 1 will be described with reference to FIG. 5. FIG. 5 is a flowchart illustrating a control method of the optical device 1.

The optical device 1 performs a phase stabilization process of the first movable portion 31 by the heat controller 4 (process S1). The heat controller 4 acquires a signal indicating the swing state of the first movable portion 31. In this embodiment, the heat controller 4 acquires a signal indicating the phase of the swing angle of the first movable portion 31 and controls the heater 15, based on the acquired signal. The heat controller 4 controls the heating of the first connection portions 41 and 42 by the heater 15 so that the phase difference between the phase of the drive signal output from the drive controller 3 and the phase of the signal indicating the swing state of the first movable portion 31 decreases. In this embodiment, the heat controller 4 provides a large heat to the first connection portions 41 and 42 by the first heater 71 and then provides a small heat to the first connection portions 41 and 42 by the second heater 72 to perform fine adjustment.

When the first connection portions 41 and 42 are heated by the heater 15, the elastic modulus of the first connection portions 41 and 42 changes. When the elastic modulus of the first connection portions 41 and 42 changes, the phase of the swing angle of the first movable portion 31 changes. The heat controller 4 acquires a signal indicating the changed phase of the swing angle of the first movable portion 31 and controls the heater 15 based on the acquired signal. That is, the heat controller 4 performs feedback control of the heater 15 based on a signal indicating the phase of the swing angle of the movable portion 23. The heat controller 4 controls the heater 15 so that the resonance frequency of the first movable portion 31 matches the frequency of the drive signal by the feedback control. When the resonance frequency of the first movable portion 31 matches the frequency of the drive signal, the phase of the swing angle of the first movable portion 31 is advanced by 90° with respect to the phase of the drive signal.

In this embodiment, the heat controller 4 detects the phase of the signal indicating the counter electromotive force of the driving coils 51 and 52. The heat controller 4 controls the heater 15 based on the difference between the phase of the signal indicating the counter electromotive force and the phase of the drive signal output from the drive controller 3. Due to the heating of the first movable portion 31, the phase of the signal indicating the counter electromotive force changes. The phase of the signal indicating the counter electromotive force corresponds to the resonance frequency of the first movable portion 31.

As the modified example of this embodiment, the optical device 1 may separately include an electromotive force monitoring coil provided in the movable portion 23. In this case, the heat controller 4 controls the heater 15 based on the difference between the phase of the signal indicating the electromotive force of the electromotive force monitoring coil and the phase of the drive signal output from the drive controller 3. That is, the signal indicating the electromotive force generated in the electromotive force monitoring coil corresponds to the signal indicating the counter electromotive force of the driving coils 51 and 52. A signal indicating inverse piezoelectricity or a signal from an optical sensor that detects the position of the first movable portion 31 may be used as a signal indicating the swing state of the first movable portion 31.

When the optical device 1 performs the phase stabilization process, the amplitude control of the first movable portion 31 is performed by the drive controller 3 (process S2). The drive controller 3 controls a current to flow to the driving coils 51 and 52, based on the amplitude of the swing of the first movable portion 31. For example, the drive controller 3 controls a current to flow to the driving coils 51 and 52, based on the peak of the signal indicating the counter electromotive force. Instead of the signal indicating the counter electromotive force of the driving coils 51 and 52, a signal or the like indicating the electromotive force generated in the electromotive force monitoring coil may be used.

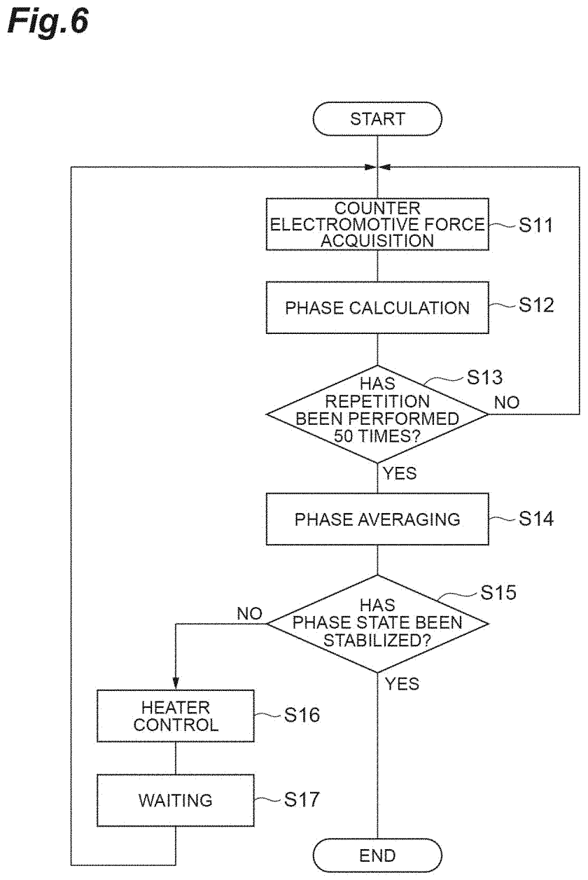

Next, an example of the phase stabilization process of the first movable portion 31 will be described in detail with reference to FIG. 6. FIG. 6 is a flowchart illustrating the phase stabilization process of the first movable portion 31.

First, the heat controller 4 acquires a signal indicating the counter electromotive force in the driving coils 51 and 52 (process S11). Subsequently, the heat controller 4 calculates the phase of the signal indicating the counter electromotive force, based on the acquired signal (process S12).

Next, the heat controller 4 determines whether or not the acquisition of the signal indicating the counter electromotive force and the calculation of the phase of the acquired signal are repeated a predetermined number of times (process S13). For example, the heat controller 4 determines whether or not the acquisition of the signal indicating the counter electromotive force and the calculation of the phase of the acquired signal are repeated 50 times (process S13). The heat controller 4 returns the process to process S11 when it is determined that the repetition is not performed 50 times (NO of process S13).

The heat controller 4 proceeds the process to process S14 when it is determined that the repetition is performed 50 times (YES of process S13). The heat controller 4 averages the phases of the signals of the counter electromotive force acquired by repeating process S11 and process S12 (process S14). In this embodiment, the heat controller 4 averages the phases of 50 signals.

Next, the heat controller 4 determines whether or not the phase of the swing angle of the first movable portion 31 is stabilized (process S15). When the resonance frequency of the first movable portion 31 matches the frequency of the drive signal, the phase of the swing angle of the first movable portion 31 is stabilized. In this embodiment, the heat controller 4 determines whether or not the phase of the swing angle of the first movable portion 31 is stabilized based on the difference between the average of the phase of the swing angle obtained by process S14 and the phase of the drive signal output from the drive controller 3. When the difference is 90°, the resonance frequency of the first movable portion 31 matches the frequency of the drive signal. The heat controller 4 determines that the phase of the swing angle of the first movable portion 31 is stabilized when the difference is within the range from 90° in consideration of the error. For example, the heat controller 4 determines that the phase of the swing angle of the first movable portion 31 is stabilized when the difference is 90±0.15°. The heat controller 4 may determine that the phase of the swing angle of the first movable portion 31 is stabilized when the maximum value of the swing angle of the first movable portion 31 becomes a predetermined value or more.

The heat controller 4 precedes the process to process S16 when it is determined that the phase is not stabilized (NO of process S15). The heat controller 4 ends the phase stabilization process when it is determined that the phase is stabilized (YES of process S15).

The heat controller 4 controls the heater 15 based on the average of the phase obtained by process S14 (process S16). The heat controller 4 controls the heater 15 based on the difference between the average of the phase and the phase of the drive signal output from the drive controller 3. The heat controller 4 heats the first movable portion 31 by the heater 15 so that the resonance frequency of the first movable portion 31 matches the frequency of the drive signal in response to the difference between the phase of the counter electromotive force and the phase of the drive signal.

The heat controller 4 determines the heat to be provided from the heater 15 to the first movable portion 31 in response to the value of the difference and controls the heater 15 so that the determined heat is supplied to the first connection portions 41 and 42. For example, the heat controller 4 determines the intensity of the laser irradiated from the laser irradiation unit 74 in response to the value of the difference. For example, the heat controller 4 determines a voltage to be applied to the heating wire portion 73 in response to the value of the difference. The heat controller 4 may control the heater 15 so that a predetermined heat is supplied to the first connection portions 41 and 42 when it is determined that the resonance frequency of the first movable portion 31 fails to match the frequency of the drive signal.

The heat controller 4 waits for a predetermined time after performing process S16 (process S17). The heat controller 4 returns the process to process S11 after waiting for a predetermined time. In this embodiment, the heat controller 4 waits for 1 second after performing process S16.

Next, the operations and effects of the optical devices of the above-described embodiment and modified examples will be described.

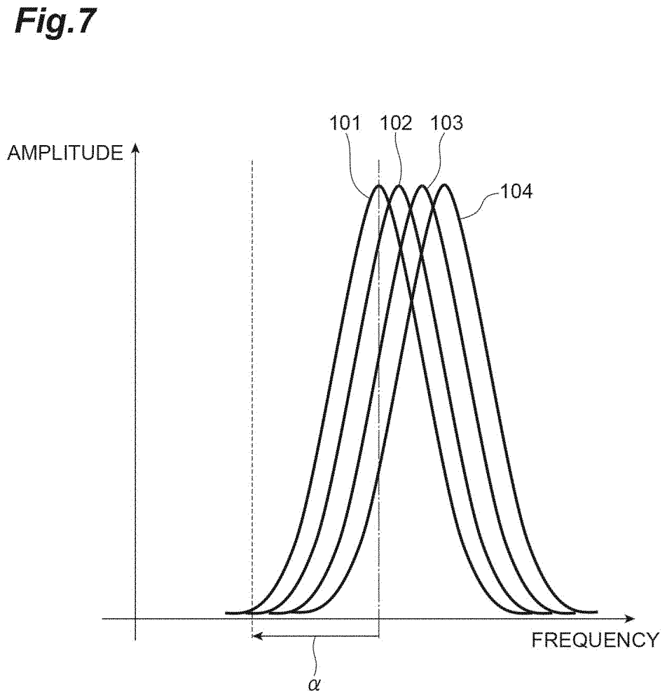

FIG. 7 illustrates a relationship between the resonance frequency of the first movable portion 31 of each mirror unit 2 and the frequency of the drive signal. The vertical axis indicates the amplitude and the horizontal axis indicates the frequency. Waveforms 101, 102, 103, and 104 indicated by the thick solid line illustrate a relationship between the amplitude and the frequency of the swing of the first movable portion 31 in a state before the first connection portions 41 and 42 are heated by the heater 15. The waveforms 101, 102, 103, and 104 respectively correspond to different first movable portions 31. Thus, the one-dotted chain line indicates the resonance frequency of the first movable portion 31 corresponding to the waveform 101. The dashed line indicates the frequency of the drive signal.

In this way, in the optical device 1, the resonance frequency of the first movable portion 31 is higher than the frequency of the drive signal of the drive controller 3. In this state, when the first connection portions 41 and 42 are heated by the heater 15, the elastic modulus of the first connection portions 41 and 42 changes. When the elastic modulus of the first connection portions 41 and 42 changes, the resonance frequency of the first movable portion 31 also changes.

When the elastic modulus of the first connection portions 41 and 42 decreases, the resonance frequency of the first movable portion 31 also decreases. Therefore, for example, when the first connection portions 41 and 42 connected to the first movable portion 31 corresponding to the waveform 101 are heated, the waveform 101 is shifted in the direction of the arrow α. Thus, the resonance frequency of the first movable portion 31 can match the frequency of the drive signal by heating the first connection portions 41 and 42. In this way, the optical device 1 can easily change the resonance frequency of the first movable portion 31 to match the frequency of the drive signal. As a result, the optical device 1 can stably swing the first movable portion 31 at a desired frequency or a desired swing angle.

In such a configuration, it is required to accurately and quickly adjust the temperature in the first connection portions 41 and 42. However, for example, when feedback control is performed based on the temperature detected by the temperature sensor, there is a time lag in detecting the temperature of the first connection portions 41 and 42 that most contribute to the change in the resonance frequency. Since the heat transferred from the first connection portions 41 and 42 to the support portion is detected when the temperature sensor is provided in the support portion 22, there is a time lag depending on the temperature transfer speed in feedback control. The heat controller 4 performs feedback control the heating of the first connection portions 41 and 42 by the heater 15, based on the phase of the signal indicating the swing state of the first movable portion 31. Therefore, the optical device 1 achieves at least more accurate and quick temperature adjustment than in the case of feedback control based on the temperature detected by the temperature sensor. The heat controller 4 can adjust the temperature of the first connection portions 41 and 42, for example, in increments of 0.003 to 0.005° C. As a result, the accuracy of changing the resonance frequency in the first movable portion 31 is also improved.

The heat controller 4 controls the heating of the first connection portions 41 and 42 in each of the plurality of mirror units 2. Therefore, the optical device 1 can change the resonance frequency of each first movable portion 31 to match the frequency of the drive signal. As a result, the optical device 1 can swing each first movable portion 31 at a desired frequency and a desired swing angle.

In a state before the first connection portions 41 and 42 are heated by the heater 15, the first movable portion 31 has a resonance frequency higher than the frequency of the drive signal output from the drive controller 3 as illustrated in FIG. 7. Therefore, the optical device 1 can allow the resonance frequency of the first movable portion 31 to match the frequency of the drive signal only according to the heating control by the heat controller 4. If the first connection portions 41 and 42 are cooled by the cooling element, the resonance frequency of the first movable portion 31 can be shifted in a direction opposite to the case of heating. However, the cooling element has a relatively large size. The optical device 1 is made more compact than the case in which a cooling element is used.

As illustrated in FIG. 7, the first movable portion 31 in each of all mirror units 2 provided in the optical device 1 has a resonance frequency higher than the frequency of the drive signal output from the drive controller 3 in a state before the first connection portions 41 and 42 connected to each first movable portion 31 are heated. The heat controller 4 heats the first connection portions 41 and 42 of all mirror units 2 by the heater 15. Thus, the optical device is made more compact than the case in which a cooling element is used.

The heat controller 4 heats the first connection portions 41 and 42 at the first power by the heater 15 and then heats the first connection portions 41 and 42 at the second power smaller than the first power. Therefore, the heat controller 4 can finely adjust the resonance frequency of the first movable portion 31 after roughly adjusting the resonance frequency of the first movable portion 31. As a result, the optical device 1 can more accurately and quickly adjust the resonance frequency of the first movable portion 31.

The heater 15 includes the first heater 71 and the second heater 72. The first heater 71 provides a first heat to the first connection portions 41 and 42. The second heater 72 provides a second heat to the first connection portions 41 and 42, and the second heat is smaller than the first heat. Therefore, the heat controller 4 can roughly adjust the resonance frequency of the first movable portion 31 by the first heater 71 and can finely adjust the resonance frequency of the first movable portion 31 by the second heater 72. Thus, the optical device 1 can more accurately and quickly adjust the resonance frequency of the first movable portion 31.

The heat controller 4 controls the heating of the first connection portions 41 and 42 by the heater 15 so that the phase difference between the phase of the drive signal output from the drive controller 3 and the phase of the signal indicating the swing state of the first movable portion 31 decreases. When comparing the phase of the drive signal with the phase of the signal indicating the swing state of the first movable portion 31, the heating of the first connection portions 41 and 42 can be more accurately controlled than the case of comparing the frequency of the drive signal with the frequency of the signal indicating the swing state of the first movable portion 31. Therefore, the optical device 1 can more accurately obtain a desired swing angle at a desired frequency.

The heater 15 of this embodiment includes the laser irradiation unit 74 which heats the first connection portions 41 and 42. Therefore, the heater 15 can more quickly heat the first connection portions 41 and 42. As a result, the optical device 1 can more accurately and quickly change the resonance frequency of the first movable portion 31. Since the temperature of the permanent magnet in the magnetic field generator 21 is unlikely to change, the change in the swing angle of the first movable portion 31 due to the change in the magnetic field is suppressed.

In the modified examples illustrated in FIGS. 3 and 4, the first heater 71 is provided in the support portion 22. The second heater 72 is provided in at least one of the first connection portions 41 and 42, the first movable portion 31, and the second movable portion 32. Therefore, the optical device 1 can more accurately and quickly adjust the resonance frequency of the first movable portion 31 in a compact configuration.

In the modified examples illustrated in FIGS. 3 and 4, the heater 15 includes the heating wires 73b, 73c, 73d, 73e, and 73f heating the first connection portions 41 and 42. The heating wires 73b, 73c, 73d, 73e, and 73f are provided in at least one of the first connection portions 41 and 42, the first movable portion 31, and the second movable portion 32 to be point-symmetrical with the center of gravity of the mirror surface 31a as a point of symmetry. Therefore, the heater 15 can accurately heat the first connection portions 41 and 42 in a compact configuration. Since the Lorentz forces generated in the heating wires 73b, 73c, 73d, 73e, and 73f cancel each other, the disturbance of the swing of the first movable portion 31 is suppressed. Since the temperature of the permanent magnet in the magnetic field generator 21 is unlikely to change, the change in the swing angle of the first movable portion 31 due to the change in the magnetic field is suppressed.

In the modified example illustrated in FIG. 4, the heating wire 73e is provided in the first movable portion 31 to surround the mirror surface 31a. Therefore, the first connection portions 41 and 42 are quickly and accurately heated. Since the Lorentz forces generated in the heating wire 73e cancel each other, the disturbance of the swing of the first movable portion 31 is suppressed.

Although the embodiment and modified examples of the present invention have been described above, the present invention is not necessarily limited to the above-described embodiment and modified examples, and various modifications can be made without departing from the gist thereof.

In this embodiment and the modified examples, an example in which the heater 15 includes the first heater 71 and the second heater 72 has been described. However, one heater 15 may be provided. For example, only one heating wire may be used as the heater 15. In this case, the heat controller 4 may change the power of the heating wire, for example, by adjusting the voltage applied to the heating wire. For example, the heat controller 4 may apply a first voltage to the heating wire and then apply a second voltage smaller than the first voltage to the heating wire. For example, the first connection portions 41 and 42 may be heated only by the heating wire 73a. The first connection portions 41 and 42 may be heated only by one of the heating wires 73b, 73c, 73d, 73e, and 73f.

The optical device 1 may use only one laser irradiation unit 74 as the heater 15. In this case, for example, the heat controller 4 may irradiate the first movable portion 31 with a laser of a first intensity from the laser irradiation unit 74 and then irradiate the first movable portion 31 with a laser of a second intensity smaller than the first intensity. Also in such a case, the heat controller 4 can roughly adjust the resonance frequency of the first movable portion 31 and then finely adjust the resonance frequency of the first movable portion 31.

In the configuration of the modified example illustrated in FIGS. 3 and 4, the laser irradiation unit 74 may be further provided. The plurality of laser irradiation units 74 may be provided in one mirror unit 2.

The heating wire 73a may be used as a resistance for a temperature sensor. When the heating wire 73a is used as the resistance for the temperature sensor, the heat controller 4 fails to allow the flow of the current to the heating wire 73a.

Both the heating wire 73a and the resistance for the temperature sensor may be provided in the support portion 22. In this case, the resistance for the temperature sensor may be provided outside or inside the heating wire 73a in a plan view. The heating wire 73a and the resistance for the temperature sensor may be provided in different layers.

The heating wire portion 73 may not be provided in the support portion 22, the movable portion 23, and the elastic connection portion 24. For example, the heating wire portion 73 may be disposed with a gap formed between the support portion 22, the movable portion 23, and the elastic connection portion 24.

In this embodiment and the modified examples, a case in which the signal indicating the swing state of the first movable portion 31 is the signal indicating the phase of the swing angle of the first movable portion 31 has been described. The signal indicating the swing state of the first movable portion 31 may be the signal indicating the phase of the speed of the first movable portion 31. In this case, the heat controller 4 determines whether or not the phase of the swing angle of the first movable portion 31 is stabilized based on the difference between the signal indicating the phase of the speed and the phase of the drive signal output from the drive controller 3. When the difference is 0°, the resonance frequency of the first movable portion 31 matches the frequency of the drive signal. The heat controller 4 determines that the phase of the swing angle of the first movable portion 31 is stabilized when the difference is in the range from 0° in consideration of the error. For example, the heat controller 4 determines that the phase of the swing angle of the first movable portion 31 is stabilized when the difference is 0±0.15°.

In this embodiment and the modified examples, an example in which the movable portion 23 is driven in two axes of the X axis and the Y axis has been described. The movable portion 23 may be driven in one axis. In this case, for example, the first movable portion 31 and the support portion 22 are connected to each other by the first connection portions 41 and 42.

In this embodiment and the modified examples, an example in which the movable portion 23 is driven by an electromagnetic method has been described. The drive type of the movable portion 23 may be a piezoelectric drive type or an electrostatic drive type.

### REFERENCE SIGNS LIST

1: optical device, 2, 2A, 2B: mirror unit, 3: drive controller, 4: heat controller, 11: mirror driver, 15: heater, 22: support portion, 23: movable portion, 24: elastic connection portion, 31: first movable portion, 31a: mirror surface, 32: second movable portion, 41, 42: first connection portion, 43, 44: second connection portion, 50: force generator, 71: first heater, 72: second heater, 73a, 73b, 73c, 73d, 73e, 73f: heating wire, 74: laser irradiation unit, P: center of gravity.

1. An optical device comprising:
a mirror driver which includes a movable portion provided with a mirror surface, an elastic connection portion connected to the movable portion, a support portion supporting the movable portion through the elastic connection portion, and a force generator configured to generate force in the movable portion;
a drive controller configured to output a drive signal that operates the force generator;
a heater configured to heat the elastic connection portion; and
a heat controller configured to control the heater,
wherein the movable portion has a resonance frequency higher than a frequency of the drive signal output from the drive controller in a state before the elastic connection portion is heated, and is configured to swing due to the elastic deformation of the elastic connection portion in response to the force of the force generator, and
wherein the heat controller is configured to acquire a signal that indicates a swing state of the movable portion, and to perform, based on a phase of the acquired signal, feedback control of heating of the elastic connection portion by the heater.

2. The optical device according to claim 1,
wherein the movable portion includes a first movable portion provided with the mirror surface, and a second movable portion surrounding the first movable portion, and
wherein the elastic connection portion includes a first connection portion elastically connecting the first movable portion to the second movable portion, and a second connection portion elastically connecting the second movable portion to the support portion.

3. The optical device according to claim 2,
wherein the heater is configured to heat the first connection portion.

4. The optical device according to claim 1,
wherein the heat controller is configured to heat the elastic connection portion at a first power by the heater and then heat the elastic connection portion at a second power smaller than the first power.

5. The optical device according to claim 1,
wherein the heater includes a first heater configured to provide a first heat to the elastic connection portion and a second heater configured to provide a second heat to the elastic connection portion, and the second heat is smaller than the first heat.

6. The optical device according to claim 5,
wherein the first heater is provided in the support portion, and
wherein the second heater is provided in at least one of the elastic connection portion and the movable portion.

7. The optical device according to claim 1,
wherein the heater includes a laser irradiation unit configured to heat the elastic connection portion.

8. The optical device according to claim 1,
wherein the heater includes a heating wire which heats the elastic connection portion, and
wherein the heating wire is provided in at least one of the elastic connection portion and the movable portion to be point-symmetrical with the center of gravity of the mirror surface as a point of symmetry.

9. The optical device according to claim 8,
wherein the heating wire is provided in the movable portion to surround the mirror surface.

10. The optical device according to claim 1,
wherein the heat controller is configured to control the heating of the elastic connection portion by the heater so that a phase difference between a phase of the drive signal output from the drive controller and a phase of the signal indicating the swing state of the movable portion decreases.

11. The optical device according to claim 1, comprising:
a plurality of mirror units each of which includes the mirror driver and the heater,
wherein the heat controller is configured to control the heating of the elastic connection portion of each of the plurality of mirror units.

12. The optical device according to claim 11,
wherein the movable portion of each of all the mirror units provided in the optical device has a resonance frequency higher than the frequency of the drive signal output from the drive controller in a state before the elastic connection portion connected to each of the movable portions is heated, and
wherein the heat controller is configured to heat the elastic connection portion of all the mirror units by the heater.
